(19) United States
(12) Patent Application Publication
(10) Pub. No.: US 2024/0201288 A1
(43) Pub. Date: Jun. 20, 2024

(54) HIGH PERFORMANCE PULSED PUMP MAGNETOMETER

(71) Applicant: Twinleaf LLC, Plainsboro, NJ (US)

(72) Inventors: Elizabeth L. Foley, Plainsboro, NJ (US); Thomas W. Kornack, Plainsboro, NJ (US); Lucia A. Rathbun, Princeton, NJ (US); Nancy G. Ford, Bordentown, NJ (US)

(21) Appl. No.: 18/389,420

(22) Filed: Nov. 14, 2023

Related U.S. Application Data
(60) Provisional application No. 63/425,446, filed on Nov. 15, 2022.

(51) Int. Cl. G01R 33/26

(52) U.S. Cl. CPC G01R 33/26

(57) ABSTRACT

Aspects of a pulsed pump magnetometer improve upon previous pulsed pump magnetometers and gradiometers with the following features: the pumping is aided with a pulsed field coil parallel to the pump light, the pump laser module uses a pulse driver circuit integrated into the sensor, the pump laser module uses a wavelength selective element integrated in the laser module but separate from the emitter, and the sensor geometry is arranged so that the dead axis can be easily reoriented by rotating the long axis of the sensor. A preferred sensor geometry, with the pump axis perpendicular to the long edge of the sensor, allows a sensor to be easily rotated to avoid a low signal condition.

### CROSS REFERENCE TO RELATED APPLICATIONS

This application claims the benefit of U.S. Provisional Patent Application No. 63/425,446 filed on Nov. 15, 2022. The disclosure of U.S. Provisional Patent Application No. 63/425,446 is hereby incorporated by reference.

### TECHNICAL FIELD

The present disclosure generally relates to magnetic field and magnetic field gradient measurements, and more particularly to a high performance pulsed pump magnetometer.

### BACKGROUND

Pulsed pump magnetometers and gradiometers use an alkali vapor in an enclosed cell subject to a period of optical pumping with a pump laser followed by a period of detection with a probe laser, wherein the atoms freely precess in the presence of a magnetic field. The frequency of the resulting free-induction decay (FID) can be measured and converted to magnetic field. Their performance is far superior to other types of magnetometers that operate in finite field; in particular they exhibit high dynamic range and linearity which enables high performance cancellation of magnetic noise.

Existing pulsed pump sensors can suffer from degraded performance due to noise caused by imperfections in the pump laser. This noise can be subtracted if the same laser is used to pump both cells in a gradiometer. Pulsed pump sensors may also suffer from degraded performance due to noise caused by imperfections in the probe laser which can be subtracted if the same laser is used to probe multiple cells.

### SUMMARY

The sensor described in the present disclosure improves upon the foundational pulsed magnetometer work described in U.S. Pat. No. 10,852,371, the contents of which are hereby incorporated by reference. Some aspects of a pulsed pump magnetometer described here improved upon previous pulsed pump magnetometers and gradiometers with the following features: the pumping is aided with a pulsed field coil parallel to the pump light, the pump laser module uses a pulse driver circuit integrated into the sensor, the pump laser module uses a wavelength selective element integrated in the laser module but separate from the emitter, and the sensor geometry is arranged so that the dead axis can be easily reoriented by rotating the long axis of the sensor. A preferred sensor geometry, with the pump axis perpendicular to the long edge of the sensor that allows the sensor to be easily rotated to avoid a low signal condition.

An embodiment of the present disclosure provides an atomic magnetometer including: a pulsed pump laser; a probe laser; an atomic vapor cell; a field coil; and a detector; wherein the pump laser is configured to generate light pulses into the atomic vapor cell along a pump axis; the field coil is configured to generate a magnetic field parallel to the pump axis; the probe laser is configured to generate a probe light into the atomic vapor cell; and the detector is configured to detect a signal from the atomic vapor cell.

An embodiment of the present disclosure provides a method of operating a magnetometer, including: providing an atomic magnetometer that includes a pump laser; a probe laser; an atomic vapor cell; a field coil; and a detector; wherein the pump laser is configured to generate light pulses into the atomic vapor cell along a pump axis; the field coil is configured to generate a magnetic field parallel to the pump axis; the probe laser is configured to generate a probe light into the atomic vapor cell; and the detector is configured to detect a signal from the atomic vapor cell; optically pumping the atomic vapor cell along the pump axis using the pulsed laser during a pumping phase with a pulse duration shorter than the Larmor period of the atoms in the atomic vapor cell; providing a probe light to the atomic vapor cell using the probe laser during a detection phase; and detecting a signal from the atomic vapor cell using the detector ..

An embodiment of the present disclosure provides a laser assembly, including: a semiconductor laser; a current pulse driver configured to pump the semiconductor laser; a wavelength-selective clement configured to transmit a selected wavelength from the semiconductor laser; and a heat source configured to heat the semiconductor laser and the wavelength-selective element; wherein the current pulse driver and the semiconductor laser are co-located in a compact package; and the laser output is tuned by temperature control of the heat source.

### BRIEF DESCRIPTION OF THE DRAWINGS

FIG. 1 is a pulsed pump magnetometer with a field coil to aid pumping according to one embodiment.

FIG. 2 is a pulsed pump magnetometer with geometry to easily reorient the dead axis by rotation according to one embodiment.

FIG. 3 is a pulsed pump laser schematic according to one embodiment.

FIG. 4 is a configuration for two adjacent emitters acting as pump and probe according to one embodiment.

### DETAILED DESCRIPTION

The description of illustrative embodiments according to principles of the present disclosure is intended to be read in connection with the accompanying drawings, which are to be considered part of the entire written description. In the description of embodiments of the disclosure herein, any reference to direction or orientation is merely intended for convenience of description and is not intended in any way to limit the scope of the present disclosure. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the disclosure are illustrated by reference to the exemplified embodiments. Accordingly, the disclosure expressly should not be limited to such exemplary embodiments illustrating some possible non-limiting combination of features that may exist alone or in other combinations of features; the scope of the disclosure being defined by the claims appended hereto.

This disclosure describes the best mode or modes of practicing the disclosure as presently contemplated. This description is not intended to be understood in a limiting sense, but provides an example presented solely for illustrative purposes by reference to the accompanying drawings to advise one of ordinary skill in the art of the advantages and construction of the certain embodiments. In the various views of the drawings, like reference characters designate like or similar parts.

It is important to note that the embodiments disclosed are only examples of the many advantageous uses of the innovative teachings herein. In general, statements made in the specification of the present application do not necessarily limit any of the various claimed disclosures. Moreover, some statements may apply to some inventive features but not to others. In general, unless otherwise indicated, singular clements may be in plural and vice versa with no loss of generality.

Several innovations are described, each of which is beneficial independently or in conjunction. The pulsed-pump magnetometer described here improves upon previous pulsed, FID magnetometers in suppressing a source of noise from the pump laser. The pump laser imposes lightshift noise, causing the atomic spin to rotate by a random amount. When combined with the systematic heading error of different atomic spin angles, the pulsed pump adds random noise. Previous work with pulsed pump gradiometers suppressed the pump laser noise by applying it in equal measure to two measurements and subtracting the result. By pulsing the pump laser while applying a strong magnetic field, the pump has a smaller influence on the initial atomic state and the lightshift has a fractionally smaller effect. Furthermore, the field applied is not uniform, so any angular excitation imparted by the pump laser rapidly decoheres, resulting in a more consistent and noise-free initial atomic state to use for measurement. The application of a field also allows the pump to be on for a longer period and imparting polarization faster than pumping in short pulses synchronous to the atomic precession.

A sensor having the pulsed pump magnetometer can suffer poor performance when the pump axis is nearly parallel to the ambient magnetic field. This dead zone can be avoided by rotating the pump axis until it is perpendicular to the total field, as shown in FIG. 2 according to an embodiment. When used in arrays, it is advantageous to make long and thin sensors to obtain high sensor density. By orienting the pumping axis perpendicular to the long edge of the sensor, it is possible to easily rotate the sensor along its long axis to avoid a dead zone. This enables one to avoid dead zones in all sensors for arbitrary sensor location.

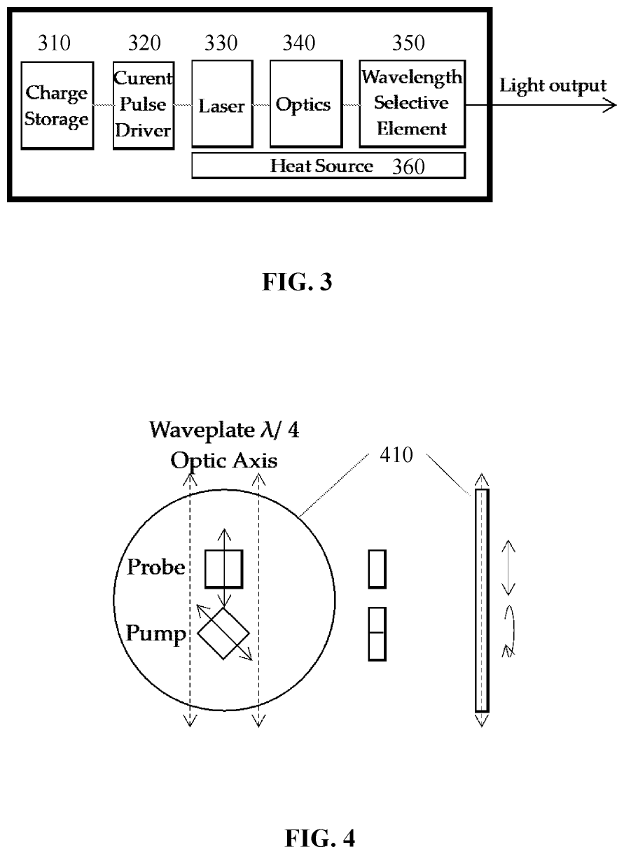

FIG. 3 shows a pulsed pump laser schematic according to an embodiment. The pulsed pump magnetometer utilizes a unique pulsed pump laser 330 with several key features designed for use in a sensitive magnetometer. The laser, commonly a multimode edge emitter laser, will pump more effectively with the wavelength narrowed so that all the photons are closer to the atomic spectral resonance. This narrowing can be accomplished using an additional wavelength-selective element 350. In some embodiment, such a wavelength-selective element is a surface or volume grating, a highly reflective mirror, or an electro-optically active material such as a liquid crystal or solid crystal. One or more optical elements 340 may be needed to direct the laser light to the wavelength-selective element, combine the laser beam with another laser beam, and/or change the polarization of light. A desirable temperature is often above the highest ambient temperature anticipated for a given application, so only heat need be added to control the temperature. The combination of the laser and wavelength-selective element is heated by a heat source 360 to the select operating wavelength according to one embodiment. The heat can be from excitation by AC or DC currents, and in one embodiment, the excitation is only turned on during periods when the sensor is not measuring to eliminate currents flowing in the sensor that would shift the magnetic field.

The laser current is pulsed using a pulsed driver 320. To achieve short pulses, the pulse driver is placed inside the sensor housing according to one embodiment. In one embodiment, a capacitor 310 is employed to store charge for the laser, and that capacitor is charged only during periods when the sensor is not measuring to eliminate currents flowing in the sensor that would shift the magnetic field. In one embodiment, the pulse driver is made with substantially non-magnetic components. In one embodiment, the minimum pulse driver consists of just two clements: a capacitor and a metal oxide semiconductor field effect transistor (MOSFET). A unique feature of this laser module is that it is controlled via a voltage applied to the capacitor and the current is limited by the resistances of the components. In one embodiment, the laser module requires a voltage, a pulse trigger, and a temperature control to tune the laser. By operating the laser at high current for short pulse times, the laser module maximizes the wall-plug efficiency, achieving 0.9 W/A in certain configurations. Note that the pulsed laser module can be used in applications other than magnetometry; anywhere a narrowed, tunable wavelength is required.

In one embodiment, a wavelength reference cell placed inside the laser module is used to lock the laser to a specific wavelength. The properties of the reference cell such as the atomic or molecular species and the gas pressure(s) are adjusted to select different wavelengths. In one embodiment, the pump laser is modulated via current or temperature to lock the laser to an absorption line.

The pump laser and probe laser are collinear in one embodiment, or perpendicular to one another in another embodiment. If collinear, their emitters may be so close as to be nearly co-located, or their emitters may be entirely separate, but the beams combined with an optical element designed to combine the beams and result in the probe polarization state linear and the pump polarization state circular according to one embodiment.

In one embodiment, the pump laser and the probe laser are from a single laser that is operated in both pumping and probing modes. The lasers may consist of a single emitter or multiple emitters.

In one configuration, two lasers may be placed adjacent and combined by allowing their divergent beams to overlap as shown in FIG. 4 according to an embodiment. A quarter waveplate 410 may be placed on the pump laser to convert its linearly polarized emission to circular polarization. If the two emitters have 45 degrees relative output polarization, the waveplate will circularize one beam and not the other. The emitters may be vertical cavity surface emitting lasers (VCSELs) or other types of lasers. They may be on the same thermal island or on separate thermal islands with separate temperature control. If the two lasers are on the same thermal island, their relative tuning can be accomplished using current control with the average tuning accomplished using temperature control according to one embodiment.

In one embodiment, the pump laser is modulated instead of pulsed. The modulation brings the laser onto the atom resonance to polarize it, and then modulates off the resonance just far enough away to reduce the polarization action.

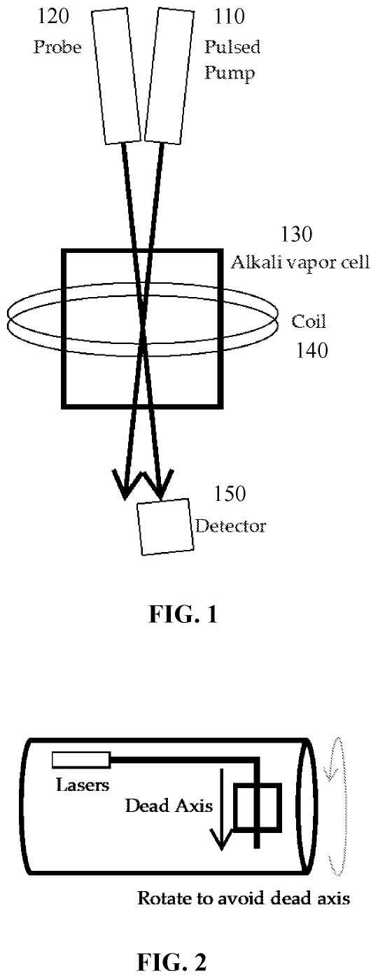

FIG. 1 shows a pulsed pump magnetometer with a field coil 140 that generates a magnetic field parallel to the pump axis to aid pumping according to an embodiment. A pulsed pump laser 110 is configured to generate light pulses into the atomic vapor cell 130 along a pump axis. Note that the atomic vapor cell can include different atoms depending on the specific operation parameters of the magnetometer. In one embodiment, the atoms in the atomic vapor cell include an alkaline metal. In another embodiment, the atoms in the atomic vapor cell include metastable Helium. The probe laser 120 is configured to generate a probe light into the atomic vapor cell. The detector 150 is configured to detect a signal from the atomic vapor cell (e.g., alkali vapor cell). In one embodiment, the detector is an intensity-based detector, e.g., photodiode. In another embodiment, the detector is polarization-based detector, e.g., a polarimeter with an analyzing polarizer and two photodiodes.

The pump pulse can be single or a train of multiple pulses at a frequency coherent with the atom precession, so the polarization is increased with every pulse. When no field coil is used, the pump pulse must be shorter than the Larmor period of the atoms. However, the field coil allows the pulse to be longer than a Larmor period and also lower in power. For example, the use of field coil is beneficial, if higher power pump lasers are not available. The field coil may be pulsed from a current source either internal or external to the sensor. It is desirable to have the coil turn off quickly; faster than the Larmor precession period, so a small coil with low inductance L is preferred to minimize L/R time. Adding extra resistance to the coil circuit as needed can speed the shutoff time. In one embodiment, the coil and laser are placed in series to simplify the circuit. In one embodiment, the laser is shut off before the coil is shut off to allow time for the atomic state to settle. In one embodiment, the field coil is attached to a surface of the vapor cell. In one embodiment, the field coil contributes to heating of the vapor cell. The magnetic field is designed to have a gradient so that atomic spin excitation is rapidly decohered according to one embodiment. In one embodiment, the field coil is fabricated using a multilayer circuit board. In one embodiment, the circuit board is flexible.

In one embodiment, a mirror or prism is used to reflect light in the sensor. The mirror is coated with a reflective coating that is designed to impart zero relative phase shift between S and P polarization states, and the reflected light does not alter its polarization state.

In one embodiment, a non-polarizing beam splitter is used to combine light from the pump laser and the probe laser. The beam splitter is coated with a partially reflective coating that is designed to impart zero relative phase shift between S and P polarization states, and the light does not change its polarization state. Circularly polarized light and linearly polarized light with any angle remain in the same polarization state.

While the present disclosure describes at some length and with some particularity with respect to the several described embodiments, it is not intended that it should be limited to any such particulars or embodiments or any particular embodiment, but it is to be construed so as to provide the broadest possible interpretation in view of the related art and, therefore, to effectively encompass various embodiments herein. Furthermore, the foregoing describes various embodiments foreseen by the inventor for which an enabling description was available. notwithstanding that modifications of the disclosure, not presently foreseen, may nonetheless represent equivalents thereto.

1. An atomic magnetometer comprising:
a pump laser;
a probe laser;
an atomic vapor cell;
a field coil; and
a detector;
wherein the pump laser is configured to generate light pulses into the atomic vapor cell along a pump axis; the field coil is configured to generate a magnetic field parallel to the pump axis; the probe laser is configured to generate a probe light into the atomic vapor cell; and the detector is configured to detect a signal from the atomic vapor cell.

2. The magnetometer of claim 1, wherein the pump laser is pulsed on one or more times during a pumping phase and switched off during a probing phase.

3. The magnetometer of claim 1, wherein the field coil is pulsed on during the pumping phase and switched off during the probing phase.

4. The magnetometer of claim 1, wherein the field coil is attached to a surface of the atomic vapor cell.

5. The magnetometer of claim 1, wherein the field coil contributes to heating of the atomic vapor cell.

6. The magnetometer of claim 2, wherein the pump laser pulsed on duration is longer than the Larmor precession period of the atomic vapor but shorter than the detection period.

7. The magnetometer of claim 1, wherein the magnetometer has a sensor geometry that is long on one axis and with the pumping axis perpendicular to the long axis.

8. The magnetometer of claim 7, where the sensor geometry can be rotated along its long axis to reorient the pumping axis.

9. The magnetometer of claim 1, wherein the pump laser is tuned by temperature with a heater designed to reach the correct pump wavelength at a temperature above the ambient operating temperature.

10. The magnetometer of claim 9, wherein the pump laser is configured to generate light with wavelength selected by an internal grating tuned by temperature.

11. The magnetometer of claim 9, wherein the pump laser is configured to generate light with wavelength selected by an external grating tuned by temperature.

12. The magnetometer of claim 1, wherein the pump laser comprises a wavelength-selective element configured to operate at a designated wavelength at the same temperature.

13. The magnetometer of claim 1, wherein the pump laser is pulsed by a pulse driver internal to a magnetometer package.

14. The magnetometer of claim 13, wherein the pulse driver is made with substantially non-magnetic components.

15. The magnetometer of claim 13, wherein the pulse driver contains a capacitor that is charged only during specific periods.

16. The magnetometer of claim 12, wherein the wavelength-selective element is a grating.

17. The magnetometer of claim 1, wherein the pump and probe lasers are arranged such that light beams from the pump laser and probe laser overlap.

18. The magnetometer of claim 17, further comprising a quarter waveplate configured to affect polarization states of the light beams from the pump and probe lasers.

19. A method of operating a magnetometer, comprising:
providing an atomic magnetometer that comprises a pump laser;
a probe laser;
an atomic vapor cell;
a field coil; and
a detector;
wherein the pump laser is configured to generate light pulses into the atomic vapor cell along a pump axis; the field coil is configured to generate a magnetic field parallel to the pump axis; the probe laser is configured to generate a probe light into the atomic vapor cell;
and the detector is configured to detect a signal from the atomic vapor cell;
optically pumping the atomic vapor cell along the pump axis using the pulsed laser during a pumping phase with a pulse duration shorter than the Larmor period of the atoms in the atomic vapor cell;
providing a probe light to the atomic vapor cell using the probe laser during a detection phase; and
detecting a signal from the atomic vapor cell using the detector.

20-26. (canceled)
